(19) United States
(12) Patent Application Publication
(10) Pub. No.: US 2025/0315358 A1
(43) Pub. Date: Oct. 9, 2025

(54) METHOD AND SYSTEM FOR DYNAMIC TEMPERATURE MEASUREMENT IN COMPUTING DEVICES

(71) Applicant: Quanta Computer Inc., Taoyuan City (TW)

(72) Inventors: Chi-Jung TSENG, Taoyuan City (TW); Che-Yuan KAO, Taoyuan City (TW)

(21) Appl. No.: 18/629,564

(22) Filed: Apr. 8, 2024

(51) Int. Cl. G06F 11/30; H05K 7/20

(52) U.S. Cl. CPC G06F 11/3058; H05K 7/20172; H05K 7/20209

(57) ABSTRACT

A temperature monitoring system in a computer system is disclosed. The system includes a heat generating component and temperature sensor measuring temperature of the heat generating component. A management controller is coupled to the temperature sensor. The management controller polls the temperature sensor at a new interval. The new interval is determined by modifying a current interval by a value determined by the measured temperature and a safety constant determined from an upper temperature threshold and a lower temperature threshold for the first heat generating component.

### TECHNICAL FIELD

The present disclosure relates generally to monitoring component temperatures in computer systems. More particularly, aspects of this disclosure relate to dynamically controlling the polling of temperature sensors.

### BACKGROUND

Computer systems (e.g., desktop computers, blade servers, rack-mount servers, etc.) are employed in large numbers in various applications. Computer systems may perform general computing operations. A typical computer system such as a server generally includes hardware components such as processors, memory devices, network interface cards, power supplies, and other specialized hardware.

Servers are employed in large numbers for high demand applications such as network based systems or data centers. The emergence of the cloud for computing applications has increased the demand for data centers. Data centers have numerous servers that store data and run applications accessed by remotely connected, computer device users. A typical data center has physical chassis structures with attendant power and communication connections. Each rack may hold multiple computing servers and storage servers. Each individual server has multiple identical hardware components such as processors, storage cards, network interface controllers, and the like.

For data centers housing hundreds of servers, “temperature control” for servers has always been a crucial matter to determine whether machine loads may risk complete component failure and therefore guarantee operation of the servers under different conditions. However, efficiently monitoring server temperatures to reduce power consumption and machine loads has been a recent issue. Current server controllers can already monitor the temperatures of various components such as the power supply unit (PSU), central processing units (CPU) s, storage devices such as hard disk drives (HDD) s or solid state drives (SSD) s, graphic processing units (GPU) s, network interface controllers (NIC), specialized integrated circuits such as ASICs or FPGAs, and the like. By reading the temperature values of these components, fan switches and speeds can be adjusted to ensure proper cooling of the components to allow continual performance.

These temperature settings are typically pre-configured reference values given to a controller such as a baseboard management controller. Temperatures are sampled from temperature sensors in proximity to and sometimes internal to the components. The sampling occurs at a set frequency. Each sampling operation requires some amount of controller computational resources. Sometimes, excessive frequent temperature readings can unnecessarily burden the controller and thus reduce its effectiveness in performing other operations.

Thus, there is a need for a method to dynamically change the frequency of a temperature polling task conducted by a controller to preserve computing resources. There is another need for a routine to adjust temperature polling for different components based on configurations for the components.

### SUMMARY

The term embodiment and like terms, e.g., implementation, configuration, aspect, example, and option, are intended to refer broadly to all of the subject matter of this disclosure and the claims below. Statements containing these terms should be understood not to limit the subject matter described herein or to limit the meaning or scope of the claims below. Embodiments of the present disclosure covered herein are defined by the claims below, not this summary. This summary is a high-level overview of various aspects of the disclosure and introduces some of the concepts that are further described in the Detailed Description section below. This summary is not intended to identify key or essential features of the claimed subject matter. This summary is also not intended to be used in isolation to determine the scope of the claimed subject matter. The subject matter should be understood by reference to appropriate portions of the entire specification of this disclosure, any or all drawings, and each claim.

According to certain aspects of the present disclosure, a temperature monitoring system in a computing system is disclosed. The temperature monitoring system includes a first temperature sensor measuring temperature of a first heat generating component. A management controller is coupled to the first temperature sensor. The management controller polls the first temperature sensor at a new interval. The controller determines the new interval by modifying a maximum interval by a value determined by the measured temperature and a safety constant determined from a first upper temperature threshold and a first lower temperature threshold for the first heat generating component.

A further implementation of the example temperature monitoring system is an embodiment where the management controller is a baseboard management controller and the computing system is a server. Another implementation is where the first temperature sensor is internal to the first heat generating component. Another implementation is where the first temperature sensor is externally positioned in proximity to the first heat generating component. Another implementation is where the first heat generating component is one of a processor, a memory device, an expansion card, or a power source. Another implementation is where the example system includes a fan coupled to the management controller providing a level of air flow. The management controller is configured to change the level of air flow based on the measured temperature. Another implementation is where the example system includes a memory accessible by the management controller. The memory stores the lower temperature threshold, the upper temperature threshold, and maximum interval of the first heat generating component. Another implementation is where the example system includes a second temperature sensor coupled to the management controller. The second temperature sensor measures the temperature of a second heat generating component. The management controller polls the second temperature sensor at a new interval. The new interval is determined by modifying a maximum interval by a value determined by the current temperature and a safety constant determined from a second upper temperature threshold and a second lower temperature threshold for the second heat generating component. Another implementation is where the example system includes a bus coupled to the first and second temperature sensors, and the management controller. The bus communicates polling requests and temperature measurements. Another implementation is where the management controller is configured to set the new interval at a minimum threshold interval if the new interval is below the minimum threshold interval.

Another disclosed example is a method of dynamically altering the interval of polling a first temperature sensor for a first heat generating component in a computing system. A first lower temperature threshold, a first upper temperature threshold, and a maximum interval for the first heat generating component is read. The first temperature sensor is polled to measure the temperature of the first heat generating component. The measured temperature is received from the first temperature sensor. A new interval for polling the first temperature sensor is determined by modifying the maximum interval by a value determined by the measured temperature and a safety constant determined from the first upper temperature threshold and the lower temperature threshold.

A further implementation of the example method is an embodiment where the management controller is a baseboard management controller and the computing system is a server. Another implementation is where the first temperature sensor is internal to the first heat generating component or externally positioned in proximity to the first heat generating component. Another implementation is where the first heat generating component is one of a processor, a memory device, an expansion card, or a power source. Another implementation is where the example method includes changing the level of air flow of a fan based on the measured temperature of the first heat generating component. Another implementation is where the example method includes storing the first lower temperature threshold, the first upper temperature threshold, and the maximum interval of the first heat generating component in a memory accessible to a management controller. Another implementation is where the example method includes reading a second lower temperature threshold, a second upper temperature threshold, and a maximum interval for a second heat generating component. A second temperature sensor is polled to measure temperature of the second heat generating component. The measured temperature from the second temperature sensor is received. A new interval for polling the second temperature sensor is determined by modifying the maximum interval by a value determined by the measured temperature and a safety constant determined from the second upper temperature threshold and the lower temperature threshold. Another implementation is where a bus is coupled to the first and second temperature sensors, and the management controller and communicates polling requests and temperature measurements. Another implementation is where the example method further includes comparing the new interval to a minimum threshold interval and setting the new interval at a minimum threshold interval if the new interval is less than the minimum threshold interval.

Another disclosed example is a computer server having a heat generating component and a temperature sensor measuring heat from the heat generating component. A memory device stores a maximum interval, an upper temperature threshold, and a lower temperature threshold for the heat generating component. A baseboard management controller is coupled to the temperature sensor and memory device. The baseboard management controller is configured to poll the temperature sensor at a new interval. The new interval is determined by modifying the maximum interval by a value determined by the measured temperature and a safety constant determined from the upper temperature threshold and the lower temperature threshold.

The above summary is not intended to represent each embodiment or every aspect of the present disclosure. Rather, the foregoing summary merely provides an example of some of the novel aspects and features set forth herein. The above features and advantages, and other features and advantages of the present disclosure, will be readily apparent from the following detailed description of representative embodiments and modes for carrying out the present invention, when taken in connection with the accompanying drawings and the appended claims. Additional aspects of the disclosure will be apparent to those of ordinary skill in the art in view of the detailed description of various embodiments, which is made with reference to the drawings, a brief description of which is provided below.

### BRIEF DESCRIPTION OF THE DRAWINGS

The disclosure, and its advantages and drawings, will be better understood from the following description of representative embodiments together with reference to the accompanying drawings. These drawings depict only representative embodiments, and are therefore not to be considered as limitations on the scope of the various embodiments or claims.

FIG. 1 is a block diagram of components of an example computer system requiring temperature monitoring of the components by a management controller, according to certain aspects of the present disclosure;

FIG. 2 is a block diagram of the management controller running an example routine that adjusts the frequency of temperature measurements and corresponding temperature sensors, according to certain aspects of the present disclosure;

FIG. 3 is a top view of a motherboard for the example computer system in FIG. 1 with different on board external temperature sensors for components, according to certain aspects of the present disclosure; and

FIG. 4 is a flow diagram of a routine executed by the management controller in FIG. 1 to adjust the rate of temperature measurement polling and collection in the computer system in FIG. 1, according to certain aspects of the present disclosure.

### DETAILED DESCRIPTION

Various embodiments are described with reference to the attached figures, where like reference numerals are used throughout the figures to designate similar or equivalent elements. The figures are not necessarily drawn to scale and are provided merely to illustrate aspects and features of the present disclosure. Numerous specific details, relationships, and methods are set forth to provide a full understanding of certain aspects and features of the present disclosure, although one having ordinary skill in the relevant art will recognize that these aspects and features can be practiced without one or more of the specific details, with other relationships, or with other methods. In some instances, well-known structures or operations are not shown in detail for illustrative purposes. The various embodiments disclosed herein are not necessarily limited by the illustrated ordering of acts or events, as some acts may occur in different orders and/or concurrently with other acts or events. Furthermore, not all illustrated acts or events are necessarily required to implement certain aspects and features of the present disclosure.

For purposes of the present detailed description, unless specifically disclaimed, and where appropriate, the singular includes the plural and vice versa. The word “including” means “including without limitation.” Moreover, words of approximation, such as “about,” “almost,” “substantially,” “approximately,” and the like, can be used herein to mean “at,” “near,” “nearly at,” “within 3-5% of,” “within acceptable manufacturing tolerances of,” or any logical combination thereof. Similarly, terms “vertical” or “horizontal” are intended to additionally include “within 3-5% of” a vertical or horizontal orientation, respectively. Additionally, words of direction, such as “top,” “bottom,” “left,” “right,” “above,” and “below” are intended to relate to the equivalent direction as depicted in a reference illustration; as understood contextually from the object(s) or element(s) being referenced, such as from a commonly used position for the object(s) or element(s); or as otherwise described herein.

The present disclosure relates to a method and system to dynamically change the frequency of the temperature polling task of a management controller monitoring components in a computer device. By adjusting the monitoring period in real-time through the management controller, the temperature data polling frequency can be reduced when components are within a safe range. Conversely, temperature monitoring frequency can be increased as danger levels rises based on an increase in the measured temperature. The example routine thus enhances the efficiency of the management controller monitoring the temperature sensors and reduces the load of the server. The example method dynamically adjusts the polling period of the management controller based on the current temperature of the components. The example method prevents excessively frequent measurements but prevents unnecessary access or delayed reporting, which could result in inadequate activation of temperature control devices such like fans, leading to system anomalies.

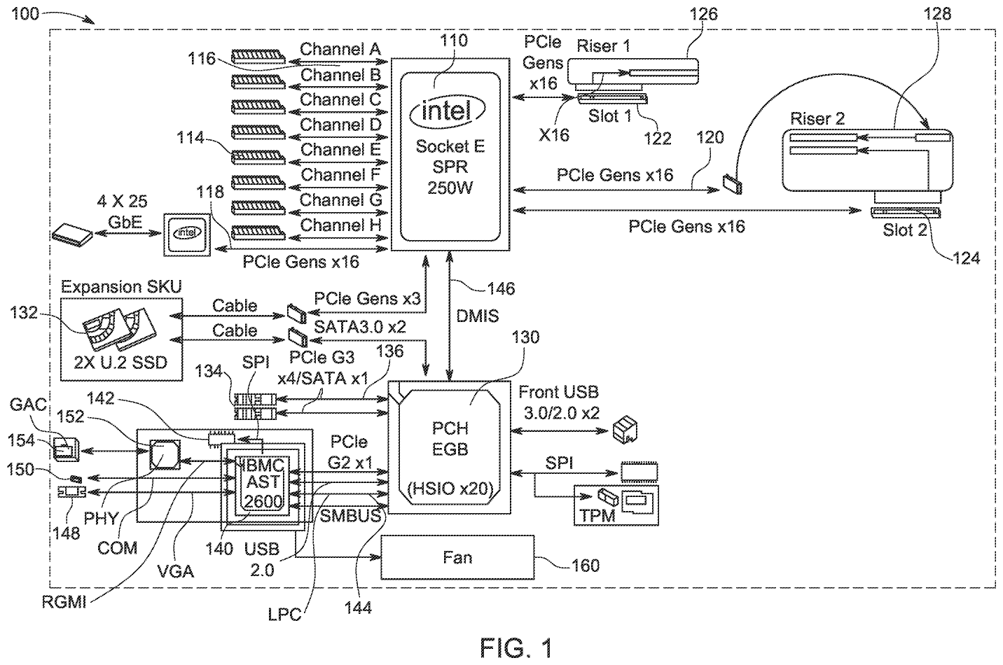

FIG. 1 a block diagram of the components of a computer system 100 that includes a management controller that runs an example routine to dynamically control the temperature measurement frequency for different components. In this example, the computer system 100 is a server system, but any suitable computer device with processing devices and associated memory components can incorporate the principles disclosed herein. The computer system 100 has a central processing unit (CPU) 110 mounted on a motherboard. The CPU 110 operates with varying processing capabilities and memory utilization based on the needs of the computer system 100. For example, the CPU 110 may execute applications frequently during certain times of the day resulting in high processing and memory utilization levels. Other times of the day may result in little to no execution of applications, resulting in low memory and processing utilization levels by the CPU 110. The operating temperature of the CPU 110 may therefore vary during times of the day. The CPU 110 may be a processor manufactured by Intel (such as a Sproket SPR), or processor offered by another manufacturer such as AMD, or other processor architecture types. Although only one CPU is shown, additional CPUs may be supported by the computer system 100. Specialized functions may be performed by specialized processors such as a GPU or a field programmable gate array (FPGA) mounted on the motherboard or on an expansion card in the computer system 100.

The CPU 110 has access to banks of dual in line memory modules (DIMMs) 114. In this example, the DIMM banks 114 constitutes the random access memory (RAM) for the CPU 110. Other processing devices may also have similar banks of DIMMs for associated RAM. A memory bus 116 allows communication between the CPU 110 and the DIMMs in the DIMM bank 114. In this example the CPU 110 has access to a PCIe Generation 4 bus 118 and a PCIe Generation 5 bus 120. In this example, the CPU 110 can access devices plugged into expansion slots 122 and 124 through the PCIe Generation 5 bus 120. In this example, a first riser 126 is connected to the expansion slot 122. The riser includes a PCIe card that is a network interface card (NIC). A second riser 128 is connected to the expansion slot 124. In this example, the second riser 128 has a PCIe card that another NIC and a PCIe second card that is a storage device.

A platform controller hub (PCH) 130 facilitates communication between the CPU 110 and other hardware components such as serial advanced technology attachment (SATA) devices, Open Compute Project (OCP) devices, and USB devices. The PCH (Platform Controller Hub)/Chipset that constitutes the PCH 130 may be an Intel PCH chip set or other control integrated circuits.

In this example, the SATA devices may include memory devices such as hard disk drives (HDD) s and solid state drives (SSD) s 132. In this example, the SATA devices such as the SSDs 132 may be addressed directly by the CPU 110 through the PCIe Generation 5 bus 120. Other hardware components such as other PCIe devices 134 may be directly accessed by the PCH 130 through a PCIe Generation 3 bus 136. The additional PCIe devices may include network interface cards (NIC), redundant array of inexpensive disks (RAID) cards, field programmable gate array (FPGA) cards, and processor cards such as graphic processing unit (GPU) cards. Such cards may be physically attached to slots in the computer system 100 or to risers such as the first and second risers 126 and 128.

A baseboard management controller (BMC) 140 manages operations, such as power management and thermal management, for the computer system 100 by monitoring the components in the computer system 100. The BMC 140 has access to a dedicated BMC memory device that is a flash memory device 142 in this example. In this example, the BMC 140 communicates with the PCH 130 through different channels 144 that may include peripheral component interconnect express (PCIe), I2C, I3C, SMBus, and general purpose input/output pins (GPIO) lines. In this example, the PCH 130 may include a series of SMBus pins for communicating with the BMC 140 through the channels 144 for memory utilization data. The PCH 130 may communicate with the CPU 110 through a Direct Media Interface (DMI)/PCIe bus 146. In this example, the BMC 140 includes a VGA port 148 and a Com port 150 that may be connected to USB devices. The BMC 140 is also connected to an Ethernet physical layer chip 152 that is coupled to dedicated NIC 154 for communication with external devices and systems.

The BMC 140 executes firmware that receives different messages from hardware components in the computer system 100 relating to operational status. The messages are stored in system logs such as a system event log (SEL) or a BMC console log that are stored on the flash memory device 142. In this example, the BMC 140 can read for temperature data from processors such as the CPU 110 from the PCH 130 in accordance with a routine that may be either in BMC firmware or stored on the flash memory device 142. Such data may be stored by the BMC 140 for later analysis of the operation of the various components. The BMC 140 monitors the health state and temperature of heat generating components in the computer system 100. These components may include the CPU, other processors, memory devices such as HDDs, SDDs, flash memory, expansion cards such as PCIe cards or OCP cards, power supplies, and the like. Based on the temperature measured for one or more of the components, the BMC 140 controls fans such as a fan 160 to keep these components working normally within acceptable temperature parameters.

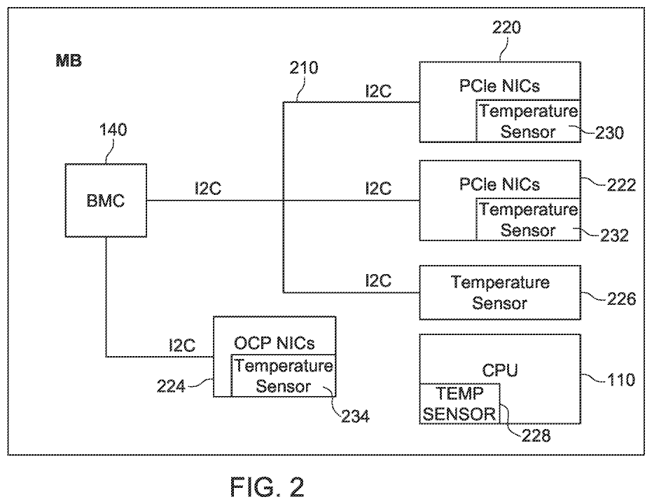

FIG. 2 shows a block diagram of example components of the computer system 100 that provide temperature data to the BMC 140. The BMC 140 is in communication with different temperature sensors and components via an I2C bus 210. Thus, polling requests may be sent via the I2C bus 210 at specified intervals to the different temperature sensors either external to or internal to the components. The temperature sensors will send measured temperatures back to the BMC 140 via the I2C bus 210 in response to the polling requests.

In this example, the components include a first PCIe NIC 220, a second PCIe NIC 222, and an OCP NIC 224. The NICs 220, 222 and 224 represent cards with components such as a network interface controller, memory, a processor and the like. On board temperature sensors such as a temperature sensor 226 may also be coupled to the I2C bus 210. Each of the example NICs 220, 222, and 224 include respective card based temperature sensors 230, 232, and 234. Other components such as the CPU 110 include internal temperature sensors such as the internal sensor 228 that communicate temperature data to the BMC 140 via the I2C 210.

In this example, the BMC 140 monitors the temperature of the components such as PCIe based components and OCP based components through internal temperature sensors coupled to the I2C bus coupled to an I2C interface on the BMC 140 at intervals determined by the example routine. Other components without built in temperature sensors may be monitored with external temperature sensors on the motherboard such as the temperature sensor 226. The example routine is also used to determine the interval of polling the external temperature sensors. Still other components have integrated internal temperature sensors and may send temperature data to the BMC 140 through a communication bus between the component and the BMC 140. After BMC 140 receives the temperature of these components, the firmware of the BMC 140 will check whether the temperature is too high for a component to function properly. The BMC 140 will control the fan 160 on the mother board to increase speed for more airflow or slow down when temperatures are within normal parameters to conserve power. In this example, when the computer system 100 is configured, a set of lower and upper temperature threshold values corresponding to each of the components associated with each of the temperature sensors is copied to the flash memory device 142. The temperatures are selected based on the component corresponding to each of the temperature sensors. In this example, different types of components have different upper critical and lower critical temperatures. The critical temperatures may be set by the operator or may be defaults from the manufacturer.

When a temperature of a component exceeds the high critical threshold value, the firmware of the BMC 140 may send an SEL log stored in the flash memory device 142 or send an e-mail to an external system over the physical layer chip 152 to alert an operator of a high temperature for the component. The example routine will increase the frequency of temperature measurements when the measured temperature approaches the high critical threshold value by dynamically increasing the run-time updating polling frequency. This allows the BMC 140 to change the fan speed more efficiently when needed. When the firmware executed by the BMC 140 determines the temperature is in proximity to the critical threshold value, the BMC 140 will send an e-mail or the SEL log to a system administrator. The BMC 140 can also reduce the loading and power consumption by reducing the polling frequency of temperature sensors when components are operating within normal parameters.

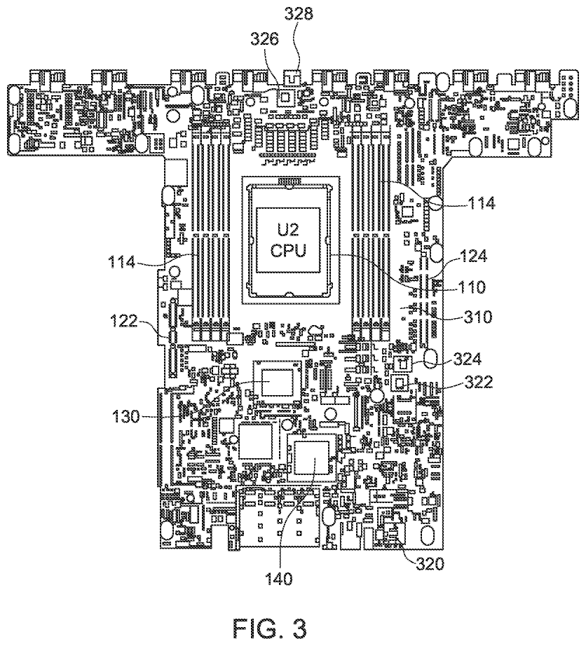

FIG. 3 is a top view of a motherboard 310 that holds the physical components in the block diagram in FIG. 2. Thus, like elements in FIG. 3 are labeled with their corresponding reference number from FIG. 2. The motherboard 310 has a series of sockets for installation of integrated circuits such as the CPU 110, the PCH 130 and the BMC 140. Additional slots are provided near the CPU 110 for the DIMM banks 114. The motherboard 310 may have the additional slots 122 and 124 for riser devices that allow for the installation of additional device cards.

In this example, the motherboard 310 may have external temperature sensors such as a temperature sensor 320 that are connected via the I2C bus to the BMC 140. In this example, the temperature sensor 320 measures the overall temperature of the motherboard 310. Other on board temperature sensors 322, 324, 326 and 328 may be provided.

In this example, a dynamic interval is used for determining when measurement of each of the temperature sensors occurs in the computer system 100 by the BMC 140. This differs from known server temperature monitoring cycles that follow a fixed frequency. In this example, the BMC 140 regularly polls the temperature sensors for various components at different dynamic intervals. The example method dynamically adjusts the periods when polling of temperature data is conducted by the BMC 140 for temperature sensors. The polling interval is determined based on the current temperature of the corresponding components and various configured values. This prevents excessively frequent, but unnecessary access or delayed reporting, which could result in inadequate activation of temperature control devices such as fans, leading to system anomalies.

A user sets an upper threshold temperature, a lower threshold temperature, and a maximum polling interval for each monitored component in the initial configuration file stored in the flash memory device 142. The example routine executed by the BMC 140 then automatically adjusts the monitoring cycle for the respective components according to the configuration values.

In this example, the maximum polling interval is S seconds as determined in the configuration file. A new polling interval is S_{new} seconds. The device temperature determined by the temperature sensor is T degrees C. The upper threshold temperature is U degrees C. and the lower threshold temperature is L degrees C. as set for the component in the configuration file. A safety coefficient is K where K=(U−L)/2. The new polling interval is determined by:

$${S}_{new} = S - \frac{\vert T - K \vert}{K} S$$

Thus, the new polling interval is a reduced frequency from the maximum frequency resulting in the BMC 140 polling the temperature sensor at a lower frequency when the device temperature is within the lower and upper thresholds. The interval is based on the absolute difference between the temperature and the safety coefficient. An additional condition is that if S_{new} is less than 1, then a lowest interval value such as 1 second is used as S_{new} to ensure that polling does not fall below a safety floor. The lowest interval value may be set by an operator.

For example, the maximum polling interval is set at S=10 seconds for an example component, the upper threshold temperature is set at U=100 C, and the lower threshold is set at L=0 C. In this example, the device temperature is measured at T=60 C. The example routine determines the new polling interval, S_{new} in accordance with the formula above. In this example, the new polling interval is 8 seconds. Thus, polling frequency increases when the device temperature is closer to the upper threshold temperature, allowing the BMC 140 to monitor a potential issue causing the increase in the temperature in the component. Correspondingly, when the device temperature is closer to the lower threshold, this indicates the device might be too cold to function normally. The device thus may start to operate abnormally. In this case, the example temperature data collection routine also increases the polling frequency to allow the BMC to preventing potential issues with low temperature.

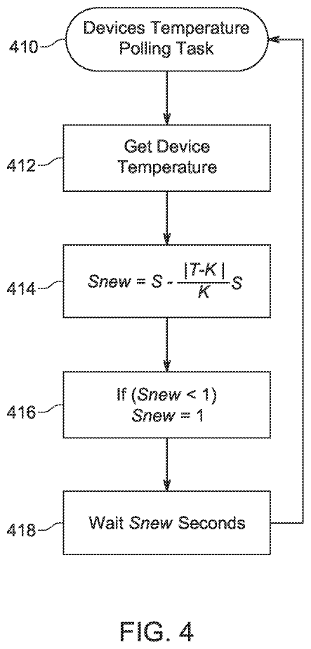

FIG. 4 is a flow chart of the temperature data dynamic collection interval routine executed by the BMC 140 in FIG. 1. The above described routine in FIG. 4 is representative of example machine-readable instructions for the BMC 140 in FIG. 1 to determine temperature polling intervals. In this example, the machine-readable instructions comprise an algorithm for execution by: (a) a processor; (b) a controller; and/or (c) one or more other suitable processing device(s). The algorithm may be embodied in software stored on tangible media such as flash memory, CD-ROM, floppy disk, hard drive, digital video (versatile) disk (DVD), or other memory devices. However, persons of ordinary skill in the art will readily appreciate that the entire algorithm and/or parts thereof can, alternatively, be executed by a device other than a processor and/or embodied in firmware or dedicated hardware in a well-known manner (e.g., it may be implemented by an application specific integrated circuit (ASIC), a programmable logic device (PLD), a field programmable logic device (FPLD), a field programmable gate array (FPGA), discrete logic device, etc.). For example, any or all of the components of the routines can be implemented by software, hardware, and/or firmware. Also, some or all of the machine-readable instructions represented by the flowcharts may be implemented manually. Further, although the example routine is described herein, persons of ordinary skill in the art will readily appreciate that many other methods of implementing the example machine-readable instructions may alternatively be used.

The example routine in FIG. 4 is run by the BMC 140 in this example for each separate temperature sensor and corresponding component. The initial configuration values of the upper and lower temperatures, maximum sampling interval and predetermined safety constant, K, are accessed by the BMC 140 from a memory such as the flash memory device 142. The internal or external temperature sensor is first polled by the BMC 140 over the I2C bus 210 at the expiration of the stored interval (410). After the temperature sensor responds with a temperature reading, the BMC 140 reads the device temperature from the I2C bus 210 (412). The BMC 140 then determines the new interval by determining an adjustment value determined by the difference between the measured temperature and safety constant as a proportion of the maximum sampling interval. The adjustment value is either added or subtracted to or from the maximum sampling interval (414). The routine then determines whether the new interval is under a minimum threshold and if the interval is under the minimum threshold, the new interval is set at the minimum threshold (416). The routine then waits for the expiration of the new interval (418) and then loops back to poll the temperature sensor (410).

Although the disclosed embodiments have been illustrated and described with respect to one or more implementations, equivalent alterations and modifications will occur or be known to others skilled in the art upon the reading and understanding of this specification and the annexed drawings. In addition, while a particular feature of the invention may have been disclosed with respect to only one of several implementations, such feature may be combined with one or more other features of the other implementations as may be desired and advantageous for any given or particular application.

While various embodiments of the present disclosure have been described above, it should be understood that they have been presented by way of example only, and not limitation. Numerous changes to the disclosed embodiments can be made in accordance with the disclosure herein, without departing from the spirit or scope of the disclosure. Thus, the breadth and scope of the present disclosure should not be limited by any of the above described embodiments. Rather, the scope of the disclosure should be defined in accordance with the following claims and their equivalents.

What is claimed is:

1. A temperature monitoring system in a computing system, the temperature monitoring system comprising:
a first temperature sensor measuring temperature of a first heat generating component; and
a management controller coupled to the first temperature sensor, the management controller polling the first temperature sensor at a new interval, wherein the management controller is configured to determine the new interval by modifying a maximum interval by a value determined by the measured temperature and a safety constant determined from a first upper temperature threshold and a first lower temperature threshold for the first heat generating component.

2. The temperature monitoring system of claim 1, wherein the management controller is a baseboard management controller and the computing system is a server.

3. The temperature monitoring system of claim 1, wherein the first temperature sensor is internal to the first heat generating component.

4. The temperature monitoring system of claim 1, wherein the first temperature sensor is externally positioned in proximity to the first heat generating component.

5. The temperature monitoring system of claim 1, wherein the first heat generating component is one of a processor, a memory device, an expansion card, or a power source.

6. The temperature monitoring system of claim 1, further comprising a fan coupled to the management controller for providing a level of air flow, wherein the management controller is configured to change the level of air flow based on the measured temperature.

7. The temperature monitoring system of claim 1, further comprising a memory accessible by the management controller, wherein the memory stores the first lower temperature threshold, the first upper temperature threshold, and the maximum interval of the first heat generating component.

8. The temperature monitoring system of claim 1, further comprising:
a second heat generating component; and
a second temperature sensor coupled to the management controller, the second temperature sensor measuring temperature of the second heat generating component, wherein the management controller polls the second temperature sensor at a new interval, wherein the management controller is configured to determine the new interval by modifying a maximum interval of the second heat generating component by a value determined by the current temperature and a safety constant determined from a second upper temperature threshold and a second lower temperature threshold for the second heat generating component.

9. The temperature monitoring system of claim 8, further comprising a bus coupled to the first temperature sensor, the second temperature sensor, and the management controller, the bus communicating polling requests and measured temperatures.

10. The temperature monitoring system of claim 1, wherein the management controller is configured to set the new interval at a minimum threshold interval if the new interval is below the minimum threshold interval.

11. A method of dynamically altering the interval of polling a first temperature sensor for a first heat generating component in a computing system, the method comprising:
reading a first lower temperature threshold, a first upper temperature threshold, and a maximum interval for the first heat generating component;
polling the first temperature sensor to measure temperature of the first heat generating component;
receiving the measured temperature from the first temperature sensor; and
determining a new interval for polling the first temperature sensor via a management controller by modifying the maximum interval by a value determined by the measured temperature and a safety constant determined from the first upper temperature threshold and the lower temperature threshold.

12. The method of claim 11, wherein the management controller is a baseboard management controller and the computing system is a server.

13. The method of claim 11, wherein the first temperature sensor is internal to the first heat generating component or externally positioned in proximity to the first heat generating component.

14. The method of claim 11, wherein the first heat generating component is one of a processor, a memory device, an expansion card, or a power source.

15. The method of claim 11, further comprising changing the level of air flow of a fan based on the measured temperature of the first heat generating component.

16. The method of claim 11, further comprising storing the first lower temperature threshold, the first upper temperature threshold, and the maximum interval of the first heat generating component in a memory accessible to the management controller.

17. The method of 11, further comprising:
reading a second lower temperature threshold, a second upper temperature threshold, and a maximum interval for a second heat generating component;
polling a second temperature sensor to measure temperature of the second heat generating component;
receiving the measured temperature from the second temperature sensor; and
determining a new interval for polling the second temperature sensor by modifying the maximum interval of the second heat generating component by a value determined by the measured temperature and a safety constant determined from the second upper temperature threshold and the lower temperature threshold.

18. The method of claim 17, wherein a bus is coupled to the first and second temperature sensors, and the management controller and wherein the bus communicates polling requests and measure temperatures.

19. The method of claim 11, further comprising comparing the new interval to a minimum threshold interval and setting the new interval at a minimum threshold interval if the new interval is less than the minimum threshold interval.

20. A computer server comprising:
a heat generating component;
a temperature sensor measuring heat from the heat generating component;
a memory device storing a maximum interval, an upper temperature threshold, and a lower temperature threshold for the heat generating component; and
a baseboard management controller coupled to the temperature sensor and memory device, the baseboard management controller polling the temperature sensor at a new interval determined by modifying a current interval by a value determined by the measured temperature and a safety constant determined from the upper temperature threshold and the lower temperature threshold.
